(19) United States
(12) Patent Application Publication
(10) Pub. No.: US 2023/0059488 A1
(43) Pub. Date: Feb. 23, 2023

(54) Common Point Ground Fault Detector

(71) Applicant: Botron Company, Inc., Phoenix, AZ (US)

(72) Inventor: Keith W. Hooley, Phoenix, AZ (US)

(73) Assignee: Botron Company, Inc., Phoenix, AZ (US)

(21) Appl. No.: 17/892,073

(22) Filed: Aug. 20, 2022

Related U.S. Application Data
(60) Provisional application No. 63/235,632, filed on Aug. 20, 2021.

(51) Int. Cl. G01R 31/52; H01R 13/66; G01R 31/66; H01R 24/78

(52) U.S. Cl. CPC G01R 31/52; H01R 13/665; G01R 31/66; H01R 24/78; H01R 13/652

(57) ABSTRACT

A common point ground fault detector monitors an outlet. The detector includes a power connection having at least hot, neutral, and ground leads for connecting to the outlet, a bench ground connector, an earth ground, to which both the ground lead and the bench ground connector are electrically connection, and through which the bench ground connector discharges electrostatic charge, and a switch electrically coupled between the earth ground and the bench ground connector. The switch enables an electrical connection between the earth ground and the bench ground connector in response to a normal operating condition of the outlet, and the switch disables the electrical connection between the earth ground and the bench ground connector in response to an abnormal operating condition of the outlet.

### CROSS-REFERENCE TO RELATED APPLICATIONS

This application claims the benefit of U.S. Provisional Application No. 63/235,632, filed Aug. 20, 2021, which is hereby incorporated by reference.

### FIELD

The present specification relates generally to electronic equipment, and more particularly to personal and ESD protective electronic equipment.

### BACKGROUND

Electronics are sensitive to electricity. The unexpected application of current to an electronic device or component during its assembly can damage or destroy the component. Even small levels of current, such as those created by the discharge of static electricity, pose hazards for some types of electronics. Minimizing accidental exposure of electronics to current is a high priority in the manufacturing, assembly, and testing of electronics.

For this reason, assembly and test benches in many factories have grounding points. Grounding points connect to earth ground and provide a low impedance path for electricity to travel to ground. This dissipates electrical charge safely and predictability, rather than erratically or through a person or an electronic device.

Common point grounds often are simply a metal block on the workbench, and the metal block connects to ground through a nearby electrical outlet. Infrequently—but not never—hot will connect to this outlet ground, either by defective wiring, a short, or other means. When this occurs, the ground becomes electrified, and so the common point ground also becomes electrified. And, anything connected to the common point ground becomes electrified as well.

This poses a serious hazard, not just to the electronic device but to the technician at the bench. The technician can be exposed directly to a fatal current. There is a great need to detect and prevent such hazards.

### SUMMARY

In an embodiment, a common point ground fault detector monitors the operating condition of a multi-conductor access to building power, such as an outlet. The detector includes a power connection having hot, neutral, and ground leads for connecting to the outlet, a bench ground connector, an earth ground, to which both the ground lead and the bench ground connector are electrically connection, and through which the bench ground connector discharges electrostatic charge, and a switch electrically coupled between the earth ground and the bench ground connector. The switch enables an electrical connection between the earth ground and the bench ground connector in response to a normal operating condition of the outlet, and the switch disables the electrical connection between the earth ground and the bench ground connector in response to an abnormal operating condition of the outlet.

In embodiments, the common point ground fault detector includes test circuitry configured to detect the normal and abnormal conditions, and a power supply configured to provide power to the test circuitry. A housing contains the switch, test circuitry, and a processor. The test circuitry is configured to detect the normal and abnormal conditions, and the processor is coupled in electric communication to the test circuitry to control the switch. The detector includes an isolated section which is electrically isolated from the leads, and a non-isolated section which is not electrically isolated from the lead. The test circuitry includes pins in the non-isolated section which are electrically coupled to the hot, neutral, and ground leads, and the test circuitry includes other pins in the isolated section which are electrically coupled to the processor. The switch includes a ground pin in the non-isolated section which is electrically coupled to the earth ground, and the switch includes a different pin in the isolated section which is electrically coupled to the processor. In embodiments, when the test circuitry detects the normal operating condition, the switch enables an electrical connection between the ground lead and the bench ground connector, and when the test circuitry detects the abnormal operating condition, the switch disables an electrical connection between the ground lead and the bench ground connector. The detector includes a processor and annunciators coupled in electrical communication with the processor to alert in response to the abnormal condition. The power connection is one of a plug and a socket, in some embodiments.

In an embodiment, a common point ground fault detector monitors an outlet and includes a power connection having hot, neutral, and ground leads for connecting to the outlet, a bench ground connector, and a switch electrically coupled between the ground lead and the bench ground connector. The switch enables an electrical connection between the ground lead and the bench ground connector in response to a normal operating condition of the outlet, and the switch disables the electrical connection between the ground lead and the bench ground connector in response to an abnormal operating condition of the outlet. Test circuitry is configured to detect the normal and abnormal conditions, and a power supply is configured to provide power to the test circuitry. A housing contains the switch, test circuitry, and a processor, wherein the test circuitry is configured to detect the normal and abnormal conditions, and the processor is coupled in electric communication to the test circuitry to control the switch. In embodiments, when the test circuitry detects the normal operating condition, the switch enables an electrical connection between the ground lead and the bench ground connector, and when the test circuitry detects the abnormal operating condition, the switch disables an electrical connection between the ground lead and the bench ground connector. In embodiments, the detector includes a processor and annunciators coupled in electrical communication with the processor to alert in response to the abnormal condition. The power connection is one of a plug and a socket, in some embodiments.

In an embodiment, a common point ground fault detector monitors an outlet and includes a housing, a power connection accessible from outside of the housing and having hot, neutral, and ground leads for connecting to the outlet. A bench ground connector is accessible from outside of the housing for connecting an ESD-sensitive object to ground. Within the housing, the detector includes test circuitry configured to detect normal and abnormal operating conditions of the outlet, a processor coupled in electric communication to the test circuitry, and a switch coupled in electric communication to the processor to receive a control signal from the processor, to the ground lead of the power connection, and to the bench ground connector. When the test circuitry detects the normal operating condition, the switch enables an electrical connection between the ground lead and the bench ground connector, and when the test circuitry detects the abnormal operating condition, the switch disables an electrical connection between the ground lead and the bench ground connector.

In embodiments, the common point ground fault detector includes an isolated section which is electrically isolated from the leads, and a non-isolated section which is not electrically isolated from the leads. The test circuitry includes pins in the non-isolated section which are electrically coupled to the hot, neutral, and ground leads, and it includes other pins in the isolated section which are electrically coupled to the processor. In embodiments, the switch includes a ground pin in the non-isolated section which is electrically coupled to the ground lead, and a different pin in the isolated section which is electrically coupled to the processor. Annunciators are coupled in electrical communication with the processor to alert in response to the abnormal condition. The power connection is one of a plug and a socket, in some embodiments.

The above provides the reader with a very brief summary of some embodiments described below. Simplifications and omissions are made, and the summary is not intended to limit or define in any way the disclosure. Rather, this brief summary merely introduces the reader to some aspects of some embodiments in preparation for the detailed description that follows.

### BRIEF DESCRIPTION OF THE DRAWING

Referring to the drawing:

FIG. 1 is a schematic illustration of a wiring diagram of a common point ground fault detector.

### DETAILED DESCRIPTION

Reference now is made to the drawings, in which the same reference characters are used throughout the different figures to designate the same elements. Briefly, the embodiments presented herein are preferred exemplary embodiments and are not intended to limit the scope, applicability, or configuration of all possible embodiments, but rather to provide an enabling description for all possible embodiments within the scope and spirit of the specification. Description of these preferred embodiments is generally made with the use of verbs such as “is” and “are” rather than “may,” “could,” “includes,” “comprises,” and the like, because the description is made with reference to the drawings presented. One having ordinary skill in the art will understand that changes may be made in the structure, arrangement, number, and function of elements and features without departing from the scope and spirit of the specification. Further, the description may omit certain information which is readily known to one having ordinary skill in the art to prevent crowding the description with detail which is not necessary for enablement. Indeed, the diction used herein is meant to be readable and informational rather than to delineate and limit the specification; therefore, the scope and spirit of the specification should not be limited by the following description and its language choices.

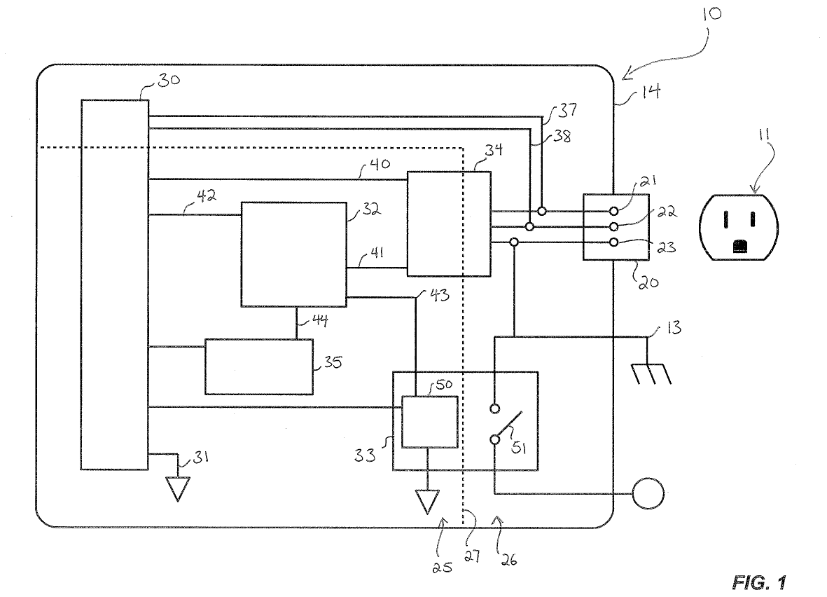

FIG. 1 illustrates schematically a wiring diagram of a common point ground fault detector 10 (hereinafter, the “detector 10”). The detector 10 is useful for installation at electronics assembly benches, electronics testing and repair benches, and like electronics tables where electronics are built, assembled, tested, maintained, and repaired.

The detector 10 monitors the operating state of a multi-conductor access to building power, such as an outlet 11. Indeed, in this description, “outlet” is used instead of “multi-conductor access to building power” for simplicity only, and without limitation, and “outlet” is meant to include all such multi-conductor accesses to building power. The outlet 11 shown in FIG. 1 is a three-wire or 110-volt outlet, but embodiments of the detector 10 are useful with four-wire or 220-volt outlets as well. The three-wire outlet 11 is shown here for the purpose of non-limiting description and discussion, and one having ordinary skill in the art will readily appreciate, after reading this description, that the detector 10 is useful with a four-wire or 220-volt outlet, too. The outlet 11 in FIG. 1 is connected to earth ground 13, as is a common point or bench ground connector 12. The bench ground connector 12 is a reliable, predictable discharge path for electrostatic charge which may accumulate and damage an electronics workpiece. The detector 10 disconnects the bench ground connector 12 when an error is detected in the operating condition of the outlet 11 or when the outlet 11 operates in an abnormal or faulty condition. Conventional ground fault circuit interrupter outlets sever the hot and neutral lines in response to detected amperage differences in those wires in an outlet. This detector 10 establishes a safe and predictable discharge path for electrostatic charge—other than through the technician or the electronic device that the technician on which the technician is working—and severs that discharge path in the event of an abnormal grounding condition.

The detector 10 includes a housing 14, shown in FIG. 1 representationally as a box drawn in a single line with rounded corners. The housing 14 is preferably enclosed for safety, with the components of the detector 10 contained within the housing 14. Those components are preferably, but not necessarily, mounted on a single printed circuit board (“PCB”) within the housing 14. The PCB is not shown in FIG. 1, but the reader will understand that the PCB is roughly the size of the housing 14 in which it is packaged.

The detector 10 is intended to be coupled to the outlet 11. The outlet 11 is outside of, external to, and separate from the detector 10. The detector 10 has at least two embodiments for connecting to the outlet 11. In an embodiment, the detector 10 has a corded plug which extends outside of the housing 14, which has male prongs, and which can be connected directly into the slots of the outlet 11. In another embodiment, the detector 10 has a socket, into which one end of a cord may be plugged (with the opposite end plugged into the outlet 11). Like the plug embodiment, the socket embodiment is accessible from outside of the housing 14, too. FIG. 1 shows both of these embodiments by generalizing them as a power connection 20 in the housing 14. The power connection has three leads: a hot lead 21, a neutral lead 22, and a ground lead 23. In embodiments of the detector 10 which have a corded plug, the plug is suitable for electrically coupling with a standard American 110V outlet 11 correspondingly having a hot slot, a neutral slot, and a ground slot. In other embodiments of the detector 10, the three leads 21, 22, and 23 simply extend directly out of the housing so that a female cord end can be plugged onto the leads 21, 22, and 23. In embodiments of the detector 10 which are useful with a four-wire or 220 volt outlet, the hot lead 21 is replaced by two hot leads. Other configurations and embodiments are considered within the scope of this disclosure as well. The ground lead 23 is coupled electrically to earth ground 13.

The bench ground connector 20 is an element positioned on or just outside the housing 14. In some embodiments, it may be in the sidewall for the housing 14, set in as a socket recessed into the sidewall. In other embodiments, the bench ground connector 12 is a metal block, a plate, an alligator clip, or the like. In some embodiments, the bench ground connector 12 may be a series of connectors, such as two, three, or more connectors spaced apart across a workbench, so as to provide better access depending on the location of the workpiece on the bench. Equipment, shelves, other items, and people tie into the bench ground connector either directly or at the remote locations.

The housing 14 of the detector 10 contains all other electronic components of the detector 10. Generally, the housing 14—and the PCB and components thereon—includes electrically isolated and non-isolated sections. The isolated section is protected from electrical contact or communication with the outlet 11 and thus is electrically isolated from the outlet 11, while the non-isolated is not necessarily protected from electrical contact or communication with the outlet 11 and thus is not necessarily electrically isolated from the outlet 11.

The electrically isolated section is generally depicted with the reference character 25 (shown here without limitation in the lower-left of the housing 14), and the electrically non-isolated section is generally depicted with the reference character 26 (shown here without limitation in the top and right of the housing 14). A rough boundary delineating the isolated and non-isolated sections is shown in broken line and marked with reference character 27. The boundary between the isolated and non-isolated sections 25 and 26 extends through some of the electronic components within the housing 14. The PCB has no connections coupling the isolated and non-isolated sections 25 and 26.

A power supply 30 is within the housing 14. A portion of the power supply 30 is in the isolated section 25 and another portion is located in the non-isolated section 26. The power supply 30 thus “straddles” the isolated and non-isolated sections 25 and 26. The power supply 30 has a set of pins positioned in the isolated section 25 and another, separate set of pins positioned in the non-isolated section 26, which are not connected to the pins in the isolated section 25. The pins are not shown in the drawing because one having ordinary skill in the art will readily understand their location with respect to the wires or leads connected to those pins in the isolated and non-isolated sections 25 and 26.

The power supply 30 is coupled to the hot and neutral leads 21 and 22 of the power connector 20 via wires 37 and 38, respectively. The power supply 30 is connected to an isolated ground 31, which is a relative ground that creates a reference ground for the test circuity of the detector 10. The isolated ground 31 is within the isolated section 25. The power supply 30 supplies power to test a processor 32, a switch or relay 33, test circuitry 34, and annunciators 35. Wires or leads in the PCB connect these electrical components. Those leads extend from the power supply on the isolated section alone and so provide power to those components regardless of the operating condition of the outlet 11.

One wire or set of wires 40 from the power supply extends to the test circuitry 34. A portion of the test circuitry 34 is in the isolated section 25 and another portion is located in the non-isolated section 26. The test circuitry 34 thus straddles the isolated and non-isolated sections 25 and 26. The test circuitry 34 has a set of pins positioned in the isolated section 25 and another, separate set of pins positioned in the non-isolated section 26, which are not connected to the pins in the isolated section 25. The pins are not shown in the drawing because one having ordinary skill in the art will readily understand their location with respect to the wires or leads connected to those pins in the isolated and non-isolated sections 25 and 26.

The test circuitry 34 is also connected to the hot, neutral, and grounds leads 21, 22, and 23. When those leads are electrically coupled to the outlet 11, the test circuitry 34 monitors the operating condition of the outlet 11. It monitors electronic characteristics for each of the leads 21, 22, and 23, such as voltage and current, and may monitor other electronic characteristics and performance. The outlet 11 operates in either a normal operating condition or in an abnormal operating condition as sampled at the leads 21, 22, and 23. By monitoring the electronic characteristics of the leads 21, 22, and 23, the test circuitry 34 is effectively monitoring the electronic characteristics of the access point to building power and thus also the electronic charateritsics both upstream and downstream from that outlet 11 providing access to the building power.

The test circuitry 34 allows a tiny amount of bleed current to flow between the leads 21, 22, and 23 and then measures the voltages and voltage differences. The test circuitry 34 produces a control signal which is transmitted along a wire or set of wires 41 to the processor 32 depending on the operating condition. The control signal provides information about the operational state of the outlet 11 based on measurements taken by the test circuitry 31. The test circuitry 34 includes a network of high-impedance resistors on the non-isolated portion of the test circuitry 34. Current will selectively flow or not flow depending on the status of the electrical connections at the leads 21, 22, and 23. Optical couplers connect the isolated and non-isolated portions of the test circuitry in data communication without coupling them in electrical communication. These couplers transmit measurements for the leads 21, 22, and 23 from the non-isolated portion to the isolated portion of the test circuitry 34 for data transmission to the processor 32.

The processor 32 is powered by the power supply 30 via a wire or set of wires 42. The power supply 30 is preferably located entirely in the isolated section 25, as are the wires 42. The processor 32 receives the control signal from the test circuitry 34 and performs processing based on pre-programmed instructions stored in the processor 32 or in local memory. The processor 32 is coupled to both the relay 33 and the annunciators 35 and provides instructions to each in response to execution of the pre-programmed instructions.

The processor 32 takes the measurements from the test circuitry 34 and determines if the operating condition of the outlet 11 is normal or abnormal. A normal operating condition includes, without limitation, conditions produced when the outlet 11 is wired in accordance with the National Electric Code (“NEC”), an earth ground connection is present, and an earth ground connection is operating per NEC requirements. There are many abnormal operating conditions. For example only, abnormal operating conditions include, but are not limited to, where the outlet 11 is not in a normal operating condition, where any leads are malfunctioning, where the ground lead 23 is electrified, where the hot and neutral leads 21 and 22 are reversed, where there is no earth ground connection, where the earth ground connection has a high impedance value, where the neutral lead 22 is open, where the hot lead 21 is open, where there is a ground fault, where the hot lead 21 is shorted, where the ground lead 23 is shorted, where there is a bootleg ground, where there is a bootleg ground and the hot and neutral leads 21 and 22 are reversed, and other conditions identified as abnormal or the like by NEC.

The processor 32 is coupled to the relay 33 via a wire or set of wires 43. The relay 33 is a switch which selectively connects and disconnects the bench ground connector 12 to the earth ground 13 and the ground lead 23. When the test circuitry 34 detects that the outlet 11 is operating in its normal operating condition, the relay 33 enables an electrical connection between the ground lead 23 and the bench ground connector 12. When the test circuitry 34 detects that the outlet 11 is operating in an abnormal operating condition, the relay 22 disables the electrical connection between the ground lead 23 and the bench ground connector 12. A coil 50 within the relay 33 controls the connection of the relay 33.

A portion of the relay 33 is in the isolated section 25 and another portion is located in the non-isolated section 26. The relay 33 thus straddles the isolated and non-isolated sections 25 and 26. The relay 33 has a set of pins positioned in the isolated section 25 and another, separate set of pins positioned in the non-isolated section 26, which are not connected to the pins in the isolated section 25. The pins are not shown in the drawing because one having ordinary skill in the art will readily understand their location with respect to the wires or leads connected to those pins in the isolated and non-isolated sections 25 and 26.

The coil 50 of the relay 33 is located on the isolated section 25, while a gate 51 in the relay 33 is located on the non-isolated section 26, so that the relay 33 is not damaged by a connection to the ground lead 23. The control signal from the processor 32 through the wire 43 controls the operation of the coil 50. For example, in an embodiment, as long as the processor 32 detects a normal operating condition of the outlet 11, the processor 32 will continue to send an instruction to the relay 33 to remain closed, and the coil 50 will stay on so that the gate 51 is closed. As another example, in an embodiment, when the processor 32 detects an abnormal operating condition of the outlet 11, the processor 32 will send an instruction to the relay 33 to open, and the coil 50 will turn off and allow the gate 51 to open 51. As yet another example, in an embodiment, when the processor 32 detects an abnormal operating condition of the outlet 11, the processor 32 will cease sending an instruction to the relay 33 to remain closer, and the coil 50 will activate to allow the gate 51 to close. In some embodiments, the relay 33 may be a mechanical switch, optically coupled switch, solid-state switch, or the like.

The annunciators 35 are coupled to the power supply 30 and to the processor 32. The annunciators 35 are haptic, visual, and/or audible alerts or other human-understandable alarms, such as a vibration, a red/green light, or a chime. The processor 32 sends a control signal along a wire or set of wires 44 to the annunciators. For example, while the outlet 11 is in a normal operating condition, the processor 32 may instruct the annunciators 35 to display a green light, and when the outlet 11 is in an abnormal operating condition, the processor 32 may instruct the annunciators 35 to display a red blinking light and a buzzing sound.

In operation, the technician plugs the plug 20 into an outlet 11. This provides power to the detector 10. The power supply 30 energizes the processor 32, relay 33, test circuitry 34, and the annunciators 35.

When the outlet 11 is in a normal operating condition, the test circuitry 31 detects a normal voltage and current and passes those readings to the processor 32 as a control signal, which may be as simple as a binary zero or one indicating normality. The processor 32 reads this information, performs analysis, and transmits a normal control signal to the relay 33 and annunciators 35. The relay 33 is normally in the closed position. In the closed position of the relay 33, the bench ground connector 12 is coupled electrically to the ground 13 and the ground lead 23 and thus the ground of the outlet 11. The technician who is connected to the bench ground connector 12 thus safely and effectively grounds himself or his tools.

So long as the outlet 11 operates normally, the bench ground connector 12 remains electrically coupled to the earth ground 13 and the ground lead 23 of the outlet 11. Likewise, the technician can continue to work while remaining safely grounded through the outlet 11.

However, in the event that an outlet 11 is miswired, or the outlet 11 breaks, or there is event that causes the outlet 11 to short and the outlet's hot to contact its ground, or the outlet 11 is otherwise operating abnormally, the detector 10 responds immediately. The test circuitry 34 detects the short between the outlet's hot and the outlet's ground and sends a signal to the processor 32. The processor 32 reads this signal and transmits a control signal to the relay 33, instructing the relay 33 to open. Preferably, the relay coil 50 de-energizes, which causes the relay 33 to open, which thereby disconnects the bench ground connector 12 from the ground lead 23 and the earth ground 13. This prevents shorted electricity at the ground lead 23 from flowing through the bench ground connector 12, through the technician's tools, through the electronic component on which the tech is working, and through the technician himself.

When the processor 32 transmits a control signal to the relay 33, it also sends an alert signal to the annunciators 35. The annunciators 35 may turn from green to red, or may issue loud chirping, or may begin to vibrate. So long as the annunciators 35 are alarming, the technician understands that the outlet 11 remains in a faulty operating condition and the outlet 11 should not be used.

A preferred embodiment is fully and clearly described above so as to enable one having skill in the art to understand, make, and use the same. Those skilled in the art will recognize that modifications may be made to the description above without departing from the spirit of the specification, and that some embodiments include only those elements and features described, or a subset thereof. To the extent that modifications do not depart from the spirit of the specification, they are intended to be included within the scope thereof.

What is claimed is:

1. A common point ground fault detector for monitoring an outlet, the detector comprising:
a power connection having at least hot, neutral, and ground leads for connecting to the outlet;
a bench ground connector;
an earth ground, to which both the ground lead and the bench ground connector are electrically connection, and through which the bench ground connector discharges electrostatic charge;
a switch electrically coupled between the earth ground and the bench ground connector; and
the switch enables an electrical connection between the earth ground and the bench ground connector in response to a normal operating condition of the outlet, and the switch disables the electrical connection between the earth ground and the bench ground connector in response to an abnormal operating condition of the outlet.

2. The common point ground fault detector of claim 1, further comprising:
test circuitry configured to detect the normal and abnormal operating conditions; and
a power supply configured to provide power to the test circuitry.

3. The common point ground fault detector of claim 1, further comprising a housing containing the switch, test circuitry, and a processor, wherein:
the test circuitry is configured to detect the normal and abnormal operating conditions; and
the processor is coupled in electric communication to the test circuitry to control the switch.

4. The common point ground fault detector of claim 3, wherein:
the common point ground fault detector includes an isolated section which is electrically isolated from the hot, neutral, and ground leads, and a non-isolated section which is not electrically isolated from the hot, neutral, and ground leads;
the test circuitry includes pins in the non-isolated section which are electrically coupled to the hot, neutral, and ground leads; and
the test circuitry includes other pins in the isolated section which are electrically coupled to the processor.

5. The common point ground fault detector of claim 4, wherein:
the switch includes a ground pin in the non-isolated section which is electrically coupled to the earth ground; and
the switch includes a different pin in the isolated section which is electrically coupled to the processor.

6. The common point ground fault detector of claim 4, wherein, when the test circuitry detects the normal operating condition, the switch enables an electrical connection between the ground lead and the bench ground connector, and when the test circuitry detects the abnormal operating condition, the switch disables an electrical connection between the ground lead and the bench ground connector.

7. The common point ground fault detector of claim 1, further comprising a processor and annunciators coupled in electrical communication with the processor to alert in response to the abnormal operating condition.

8. The common point ground fault detector of claim 1, wherein the power connection is one of a plug and a socket.

9. A common point ground fault detector for monitoring an outlet, the detector comprising:
a power connection having at least hot, neutral, and ground leads for connecting to the outlet;
a bench ground connector;
a switch electrically coupled between the ground lead and the bench ground connector; and
the switch enables an electrical connection between the ground lead and the bench ground connector in response to a normal operating condition of the outlet, and the switch disables the electrical connection between the ground lead and the bench ground connector in response to an abnormal operating condition of the outlet.

10. The common point ground fault detector of claim 9, further comprising:
test circuitry configured to detect the normal and abnormal operating conditions; and
a power supply configured to provide power to the test circuitry.

11. The common point ground fault detector of claim 9, further comprising a housing containing the switch, test circuitry, and a processor, wherein:
the test circuitry is configured to detect the normal and abnormal operating conditions; and
the processor is coupled in electric communication to the test circuitry to control the switch.

12. The common point ground fault detector of claim 11, wherein, when the test circuitry detects the normal operating condition, the switch enables an electrical connection between the ground lead and the bench ground connector, and when the test circuitry detects the abnormal operating condition, the switch disables an electrical connection between the ground lead and the bench ground connector.

13. The common point ground fault detector of claim 9, further comprising a processor and annunciators coupled in electrical communication with the processor to alert in response to the abnormal operating condition.

14. The common point ground fault detector of claim 9, wherein the power connection is one of a plug and a socket.

15. A common point ground fault detector for monitoring an outlet, the detector comprising:
a housing;
a power connection accessible from outside of the housing and having at least hot, neutral, and ground leads for connecting to the outlet;
a bench ground connector accessible from outside of the housing for connecting an electrostatic-discharge-sensitive object to ground; and
within the housing:
test circuitry configured to detect normal and abnormal operating conditions of the outlet;
a processor coupled in electric communication to the test circuitry;
a switch coupled in electric communication to the processor to receive a control signal from the processor, to the ground lead of the power connection, and to the bench ground connector; and
when the test circuitry detects the normal operating condition, the switch enables an electrical connection between the ground lead and the bench ground connector, and when the test circuitry detects the abnormal operating condition, the switch disables an electrical connection between the ground lead and the bench ground connector.

16. The common point ground fault detector of claim 15, wherein:
the common point ground fault detector includes an isolated section which is electrically isolated from the hot, neutral, and ground leads, and a non-isolated section which is not electrically isolated from the hot, neutral, and ground leads;
the test circuitry includes pins in the non-isolated section which are electrically coupled to the hot, neutral, and ground leads; and
the test circuitry includes other pins in the isolated section which are electrically coupled to the processor.

17. The common point ground fault detector of claim 16, wherein:
the switch includes a ground pin in the non-isolated section which is electrically coupled to the ground lead; and
the switch includes a different pin in the isolated section which is electrically coupled to the processor.

18. The common point ground fault detector of claim 15, further comprising annunciators coupled in electrical communication with the processor to alert in response to the abnormal operating condition.

19. The common point ground fault detector of claim 15, wherein the power connection is one of a plug and a socket.
